(19) United States
(12) Patent Application Publication
(10) Pub. No.: US 2025/0254946 A1
(43) Pub. Date: Aug. 7, 2025

(54) SEMICONDUCTOR DEVICES WITH LOWERED EPITAXIAL SOURCE/DRAIN REGIONS AND METHODS OF FABRICATION THEREOF

(71) Applicant: TAIWAN SEMICONDUCTOR MANUFACTURING COMPANY, LTD., Hsinchu (TW)

(72) Inventors: Tien-Yu YI, Taoyuan (TW); Chien-I KUO, Hsinchu (TW); Ming-Hua YU, Hsinchu (TW); Chii-Horng LI, Hsinchu (TW)

(21) Appl. No.: 18/431,950

(22) Filed: Feb. 3, 2024

(51) Int. Cl. H01L 29/08; H01L 29/06; H01L 29/423; H01L 29/66; H01L 29/775

(52) U.S. Cl. CPC H10D 62/151; H10D 30/014; H10D 30/43; H10D 30/6735; H10D 62/121; H10D 64/017; H10D 64/018

(57) ABSTRACT

Embodiments of the present disclosure relate to a semiconductor device with lowered source/drain regions to reduce channel resistance (R_{ch}) and source/drain contact resistance loading.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area. As minimum feature size reduces, side effects, such as leakage, parasitic devices, resistance degradation, etc., may occur. Therefore, there is a need to solve the above problems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1Q schematically demonstrate a semiconductor device according to embodiments of the present disclosure.

FIG. 2 is a flow chart of a method for manufacturing of a semiconductor substrate according to embodiments of the present disclosure.

FIGS. 3A-3J schematically illustrate various stages of manufacturing a semiconductor device according to embodiments of the present disclosure.

FIG. 4 is a flow chart of a method for manufacturing of a semiconductor substrate according to embodiments of the present disclosure.

FIGS. 5A-5C schematically illustrate various stages of manufacturing a semiconductor device according to embodiments of the present disclosure.

FIG. 6 is a flow chart of a method for manufacturing of a semiconductor substrate according to embodiments of the present disclosure.

FIGS. 7A-7D schematically illustrate various stages of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

Embodiments of the present disclosure relate to a semiconductor device including a nanosheet channel region with reduced channel resistance (Rch) and reduced source/drain contact resistance loading. Particularly, embodiments of the present disclosure provide a GAA semiconductor device with reduced channel resistance and contact resistance loading for source/drain epitaxial regions in P-type FETs. Embodiments of the present disclosure provide a GAA device including a source/drain region having a bottom surface extended below a top surface of the substrate on which a channel stack is formed. By lowering the source/drain regions, embodiments of the present disclosure increase the volume of the source/drain regions, introduce additional stress to the source/drain regions and improve uniformity of a top surface of the source/drain regions, thus, reducing channel resistance, improving mobility, and reducing resistance loading in source/drain contacts.

In some embodiments, the GAA device includes a buried epitaxial layer. The source/drain regions are formed over the buried epitaxial layer. Location and profile of the bottom surface of the source/drain region conform with a top surface of the buried epitaxial layer. In some embodiments, the top surface of the buried epitaxial layer may be controlled by selecting suitable epitaxial growth parameters. In some embodiments, a bottom dielectric film may e formed between the buried epitaxial layer and the source/drain region.

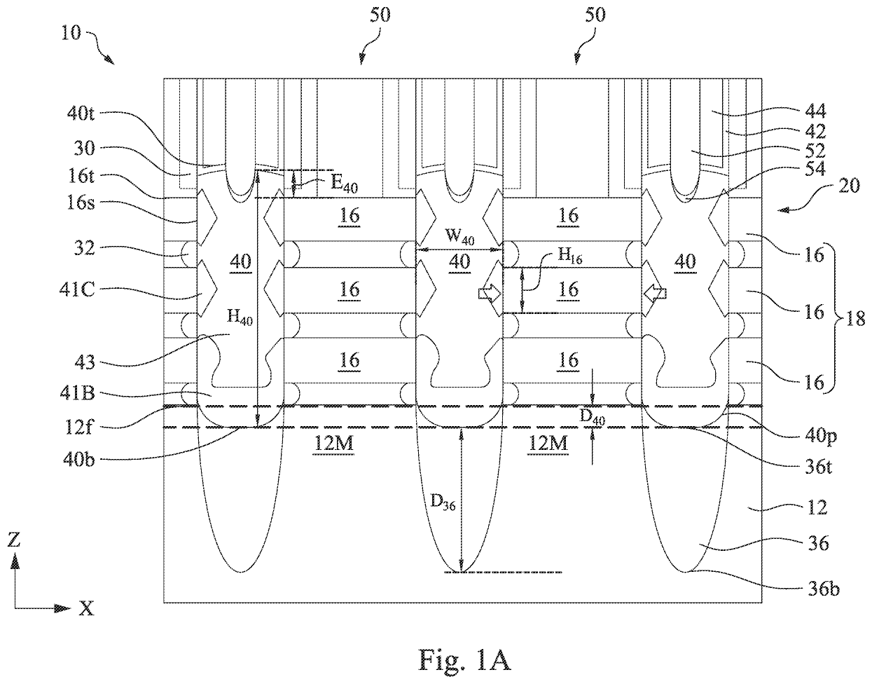

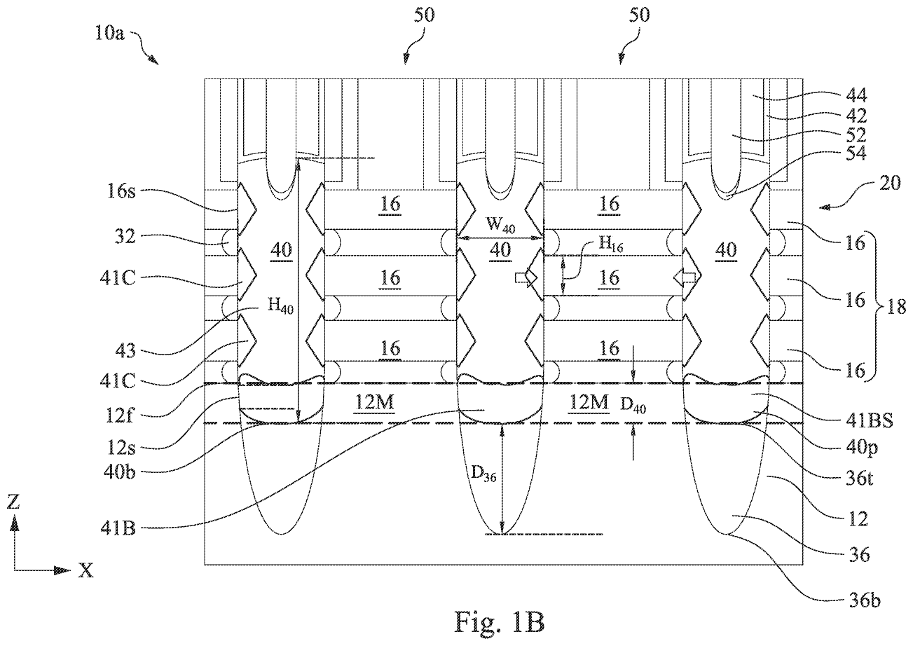

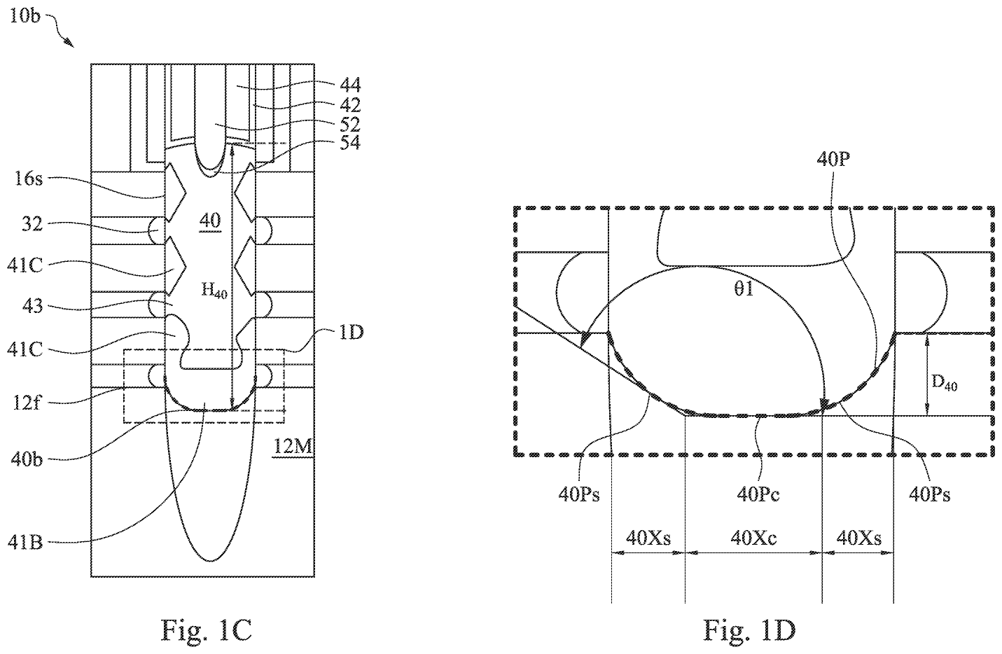

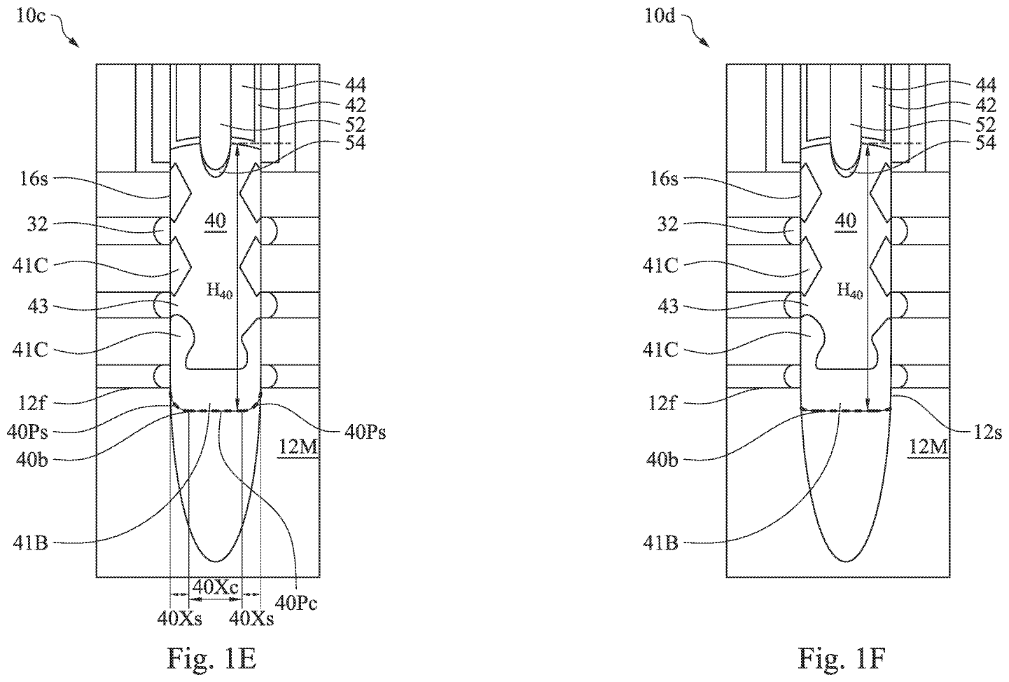

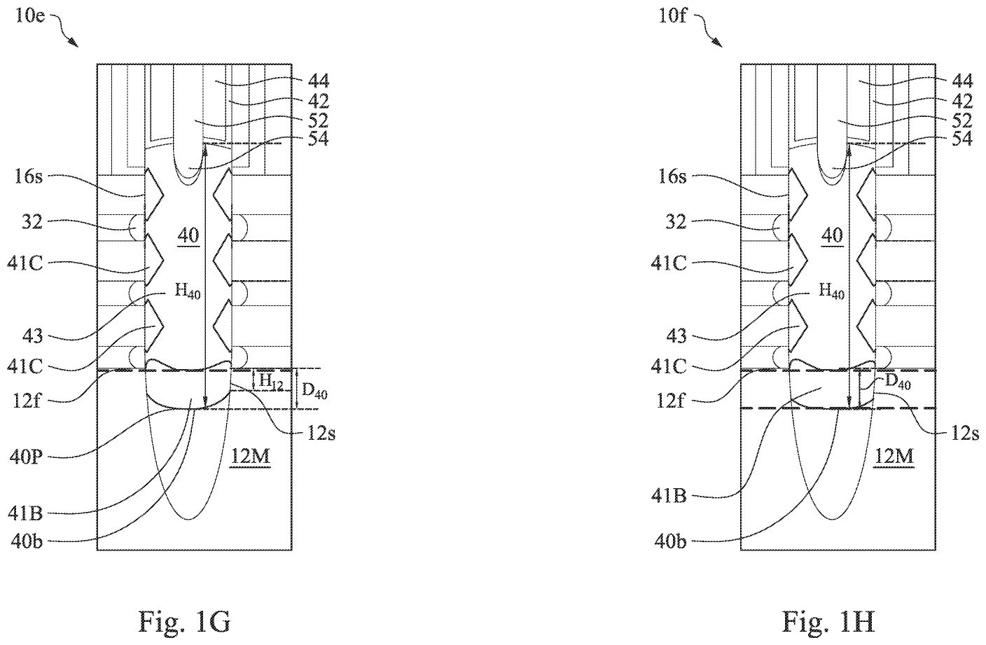

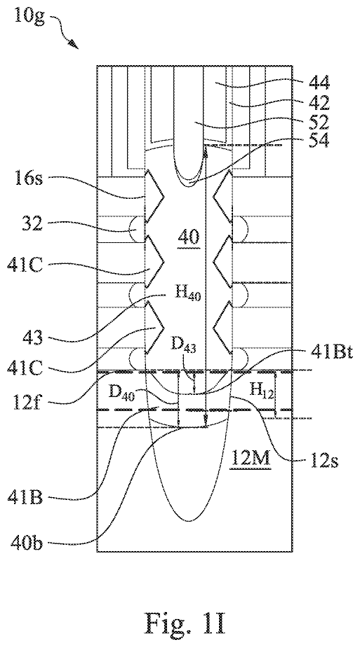

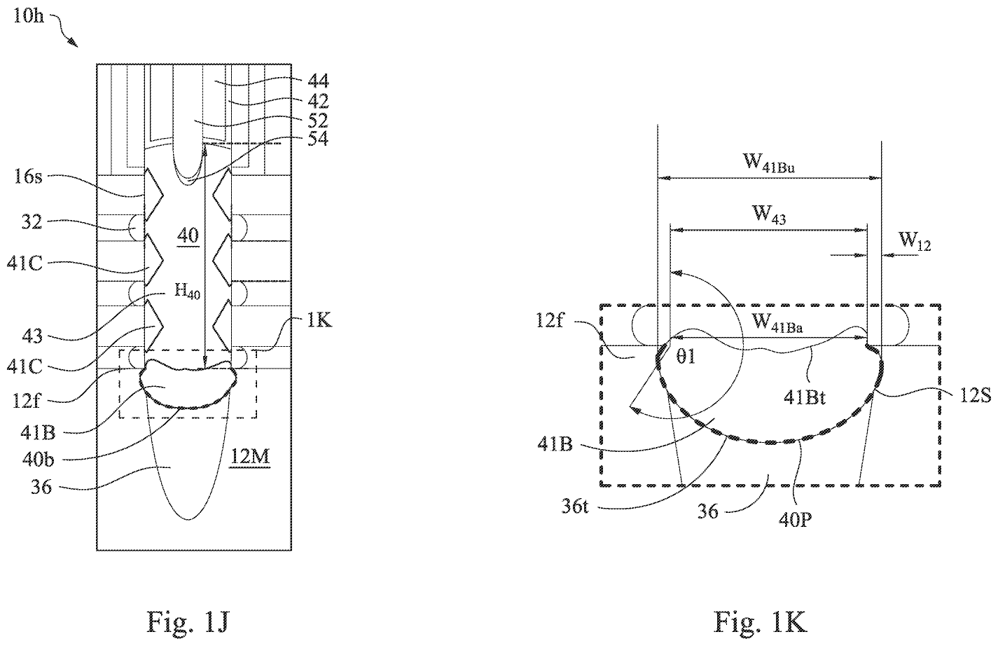

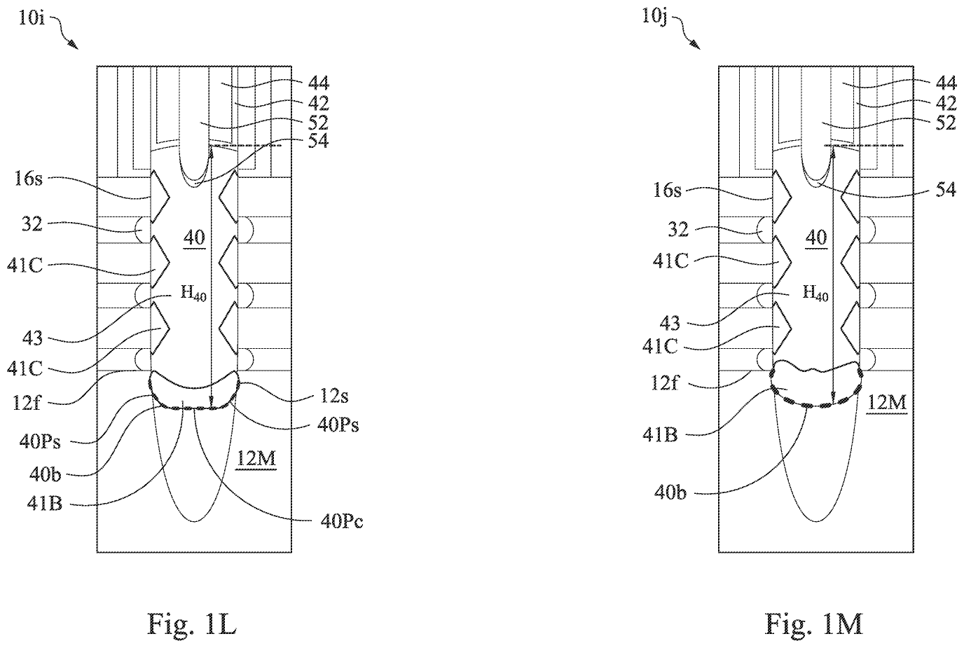

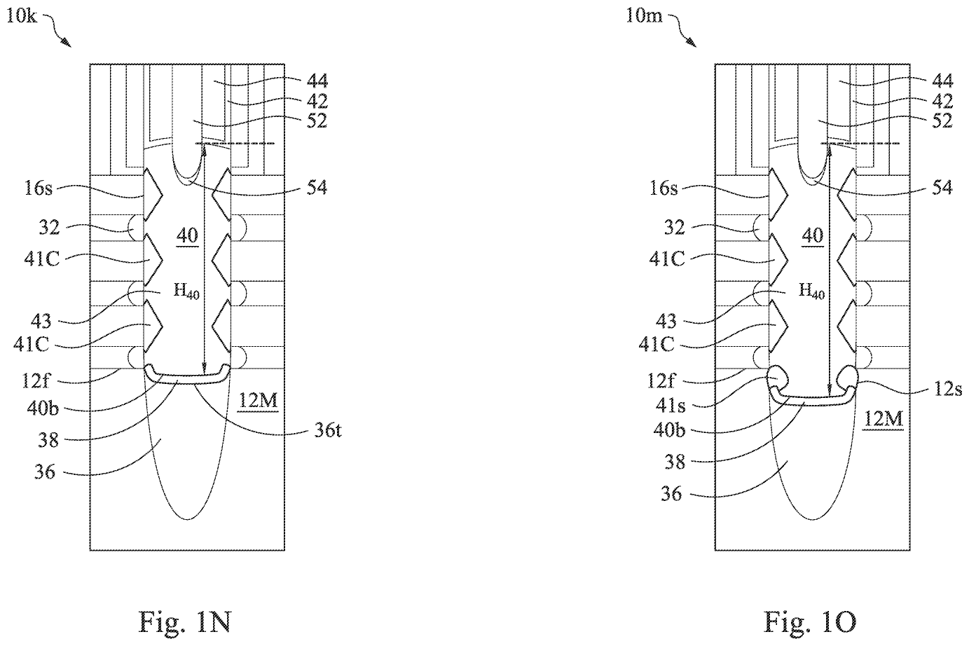

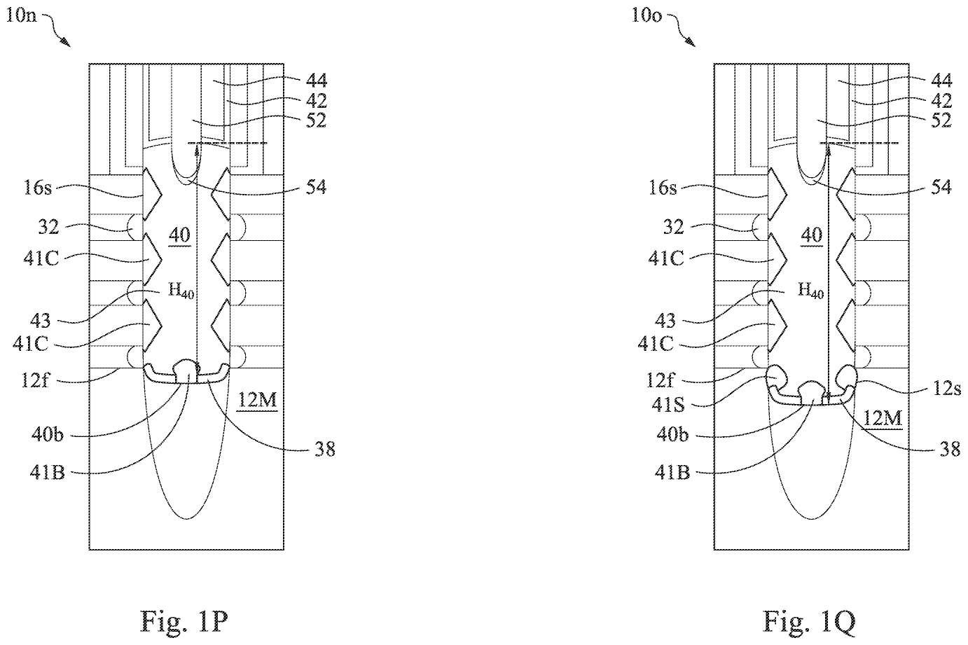

FIG. 1A schematically demonstrates a semiconductor device 10 according to embodiments of the present disclosure. FIG. 1A is a cross-sectional view of the semiconductor device 10 according to the present disclosure.

The semiconductor device 10 is a GAA device including semiconductor channels 16 formed between epitaxial source/drain regions 40. Gate structures 50 are formed over and surrounding the semiconductor channels 16. The semiconductor device 10 is formed by depositing a stack 18 including semiconductor layers 16 formed over a top surface 12f of a substrate 12, patterning the stack 18 and the substrate 12 into fins 20, forming sacrificial gate structures over the fins 20, recessing the fins 20 outside the sacrificial gate structures to form the epitaxial source/drain regions 40, and replacing the sacrificial gate structures with the gate structures 50. Sidewall spacers 30 are disposed on sidewalls of the gate structures 50. Inner spacers 32 may be disposed between the gate structures 50 and the source/drain regions 40.

In some embodiments, a bottom profile 40p of the source/drain region 40 dips below the top surface 12f of the semiconductor substrate 12. In other words, at least a portion of the bottom profile 40p for the source/drain region 40 extends down along the z-direction to a level between mesa regions 12M of the semiconductor substrate 12. The mesa regions 12M are referred to a well portion of the fins 20, which is formed from the semiconductor substrate 12 during formation of the fins 20. The bottom profile 40p of the source/drain region 40 has a bottom level 40b.

A buried epitaxial layer 36 is disposed between the source/drain region 40. The buried epitaxial layer 36 may be an epitaxial semiconductor layer formed in the recess in the semiconductor substrate 12 between the mesa regions 12M. The buried epitaxial layer 36 is in contact with a shallow trench isolation layer (not shown) and/or sidewall spacers 30. In some embodiments, the buried epitaxial layer 36 is an epitaxial semiconductor material formed from the semiconductor substrate 12. The buried epitaxial layer 36 may be a transitional layer between the crystalline structures of the semiconductor substrate 12 and the epitaxial source/drain region 40. In some embodiments, the buried epitaxial layer 36 may be used as an alignment feature for forming backside source/drain contacts.

The epitaxial source/drain region 40 are formed from the semiconductor channel layers 16 and a top surface 36t of the buried epitaxial layer 36. In some embodiments, the top surface 36t of the buried epitaxial layer 36 is formed to achieve desirable bottom profile 40p of the source/drain region 40. The top surface 36t is formed below the top surface 12f of the substrate 12, thus, allowing formation of the source/drain region 40 below the top surface 12f and increasing volume of the source/drain region 40. The increased volume of the epitaxial source/drain region 40 adds compressive force F to the semiconductor channel layers 16. The increased compressive force F causing compressive strain in the semiconductor channel layers 16 thereby increasing mobility of the channel region. The semiconductor channels 16 are separated by inner spacers 32 and are surrounded by the replacement gate 50. The gate structure 50 may be a gate stack including an interfacial layer, a gate dielectric layer, and agate electrode layer. The gate electrode layer may further include one or more work function layers and one or more metal fill layers. Sidewall spacers 30 are disposed between the epitaxial source/drain regions 40 and the gate structure 50.

The semiconductor device 10 may further include source/drain contacts 52 disposed on the epitaxial source/drain regions 40. A silicide layer 54 may be formed between the source/drain contacts 52 and the epitaxial source/drain regions 40 to facilitate electrical connection therebetween. A contact etch stop layer (CESL) 42 is deposited over the epitaxial source/drain regions 40 to protect the epitaxial source/drain regions 40 during formation. An interlayer dielectric (ILD) 44 is deposited over the CESL 42 to provide electrical isolation to the S/D contacts 52 and the epitaxial source/drain regions 40.

During operation, when a gate bias greater than a threshold voltage is applied on the gate structure 50, a conductive channel is formed within the semiconductor channel layers 16. If appropriate bias is applied to the epitaxial source/drain regions 40 via the source/drain contacts 52, current flows between the epitaxial source/drain regions 40 through the channels formed within the semiconductor channel layers 16. During the above operating condition, a portion of the gate structure 50 closest to the mesa region 12M can form a parasitic FET. If the epitaxial source/drain regions 40 were in physical contact with the mesa region 12M, an unwanted leakage current could flow between the epitaxial source/drain region 40 via the mesa portion 12M. The bottom dielectric layer 38 in the semiconductor device 10 offers adequate electrical isolation to the epitaxial source/drain regions 40 and leakage current suppression.

In some embodiments, the semiconductor device 10 is formed on a bulk semiconductor substrate 12, e.g., as opposed to an SOI substrate. In some embodiments, the semiconductor substrate 12 includes crystalline silicon (Si) or another elementary semiconductor, such as germanium (Ge). Alternatively the semiconductor substrate 12 may include (i) a compound semiconductor like silicon carbide (SiC), gallium arsenide (GaAs), gallium phosphide (GaP), indium phosphide (InP), indium arsenide (InAs), and/or indium antimonide (InSb); (ii) an alloy semiconductor like silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and/or gallium indium arsenide phosphide (GaInAsP); or (iv) combinations thereof.

The stack 18 may include the semiconductor channel layers 16 alternatively arranged with sacrificial layers (not shown). In some embodiments, the number of semiconductor channel layers 16 is between 1 and 6. The semiconductor channel layers 16 may be formed by a molecular beam epitaxy (MBE) process, a metalorganic chemical vapor deposition (MOCVD) process, and/or other suitable epitaxial growth processes. In some embodiments, the semiconductor channel layers 16 may include the same material as the substrate 10. In some embodiments, the semiconductor channel layers 16 may include different materials than the substrate 10. In some embodiments, the semiconductor channel layers 16 and the sacrificial semiconductor layers are made of materials having different lattice constants. In some embodiments, the sacrificial layers include epitaxially grown silicon germanium (SiGe) layers and the semiconductor channel layers 16 include epitaxially grown silicon (Si) layers. In some embodiments, the sacrificial layers may be dielectric layers, such as silicon oxide. Alternatively, in some embodiments, either of the semiconductor channel layers 16 and the sacrificial layers may include other materials such as Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof.

In some embodiments, each of the semiconductor channel layer 16 has a channel height H16 along the z-direction in a range between about 5 nm and about 15 nm. In some embodiments, the semiconductor channel layers 16 in the stack 18 are uniform in channel height H16. In some embodiments, the semiconductor channel layers 16 in the stack 18 have variation in the channel height H16.

In some embodiments, for a p-type device, the epitaxial source/drain regions 40 may include boron-doped (B-doped) silicon-germanium (SiGe), B-doped germanium (Ge), B-doped germanium-tin (GeSn), or combinations thereof. In some embodiments, for an n-type device, the epitaxial source/drain regions 40 may include arsenic (As) or phosphorous (P)-doped silicon (Si), carbon-doped silicon (Si:C), or combinations thereof.

In some embodiments, the epitaxial source/drain regions 40 can include two or more epitaxially-grown layers. For example, as shown in FIG. 1A, the epitaxial source/drain regions 40 may include a first epitaxial source/drain layer 41 and a bulk epitaxial source/drain layer 43. The first epitaxial source/drain layer 41 is grown from sidewall 16s of the semiconductor layer 16 and the top surface 36t of the buried epitaxial layer 36. The first epitaxial source/drain layer 41 starts as discreet sections from the exposed semiconductor surfaces. For example, the first epitaxial source/drain layer 41 includes channel sections 41C grown from the sidewall 16s of the semiconductor layer 16, and a bottom section 41B grown from the buried epitaxial layer 36. The first epitaxial source/drain layer 41 is grown to a desired thickness to enable quality crystalline growth in the subsequent bulk epitaxial growth. The channel sections 41C, and the bottom section 41B may have different physical characters, such as thickness, shape, or surface orientation, because of the different surface orientation, material and/or location of the corresponding seed layers. In some embodiments, the bottom most channel sections 41C may merge with the bottom section 41B.

The first epitaxial source/drain layer 41 may include one or more layers of Si, SiP, SiC and SiCP for NFET or Si, SiGe, Ge for a PFET. For the PFET, p-type dopants, such as boron (B), may also be included in the first epitaxial source/drain layer 241. For NFET, n-type dopants, such as arsenic (As), phosphorous (P), or carbon (C), or combinations thereof, may also be included in the first epitaxial source/drain layer 41.

In some embodiments, the semiconductor device 10 is a p-type device and the first epitaxial source/drain layer 41 includes Si or SiGe with a p-type dopant, such as B or Ga. In some embodiments, the first epitaxial source/drain layer 41 may include Si1-xGexB, wherein x is in a range between 0 and 0.5 and B concentration in a range between 1E19 atom*cm-3 and 3E21 atom*cm-3.

The bulk epitaxial source/drain layer 43 is formed over the first epitaxial source/drain layer 41. The bulk epitaxial source/drain layer 43 fills source/drain recess. Even though only one layer is shown in FIG. 1A, the bulk epitaxial source/drain layer 43 may include two or more layers. The bulk epitaxial source/drain layer 43 is epitaxially grown from the first epitaxial source/drain layer 41. The bulk epitaxial source/drain layer 43 has a higher concentration of dopants than the first epitaxial source/drain layer 41. In some embodiments, composition of the bulk epitaxial source/drain layer 43 is also different from the first epitaxial source/drain layer 41. The bulk epitaxial source/drain layer 43 and the first epitaxial source/drain layer 41 have different crystalline structures. The bulk epitaxial source/drain layer 43 may include one or more layers of Si, SiP, SiC and SiCP for NFET or Si, SiGe, Ge for a PFET. For the PFET, p-type dopants, such as boron (B), are also included in the bulk epitaxial source/drain layer 43. For NFET, n-type dopants, such as arsenic (As), phosphorous (P), or carbon (C), or combinations thereof, are included in the bulk epitaxial source/drain layer 43.

In some embodiments, the semiconductor device 10 is a p-type device and the bulk epitaxial source/drain layer 43 includes Si or SiGe with a p-type dopant, such as B or Ga. In some embodiments, the bulk epitaxial source/drain layer 43 may be Si1-xGexB, wherein x is in a range between 0.3 and 0.8 and B concentration in a range between 1E20 atom*cm-3 and 5E21 atom*cm-3.

In some embodiments, the epitaxial source/drain regions 40 have a width W40 along the x-direction in a range between about 9 nm and about 32 nm. In some embodiments, the epitaxial source/drain regions 40 have a source/drain height H40 along the z-direction in a range between about 20 nm and about 105 nm. The height H40 is increased because bottom portions of the epitaxial source/drain regions 40 grow from the buried epitaxial layer 36 which is below the top surface 12f of the mesa portion 12M or the bottom of the stack 18. In some embodiments, a drop height D40 of the epitaxial source/drain regions 40, which is defined by the distance between the top surface 12f of the mesa portion 12M and a bottom level 40b of the epitaxial source/drain regions 40, is in a range between about 5 nm and about 20 nm. In some embodiments, a ratio of the drop height D40 over the source/drain height source/drain height H40 is in a range between about 5% and about 50%.

In some embodiments, the buried epitaxial layer 36 is undoped semiconductor layer. For example, the buried epitaxial layer 36 may include Si, SiB, Si1-xGex, or Si1-xGexB, wherein x is in a range between 0 and 0.5 and B concentration in a range between 1E19 atom*cm-3 and 3E21 atom*cm-3. In some embodiments, the buried epitaxial layer 36 has a height H36 along the z-direction in a range between about 0 nm and about 50 nm. In some embodiments, a depth of D36 of the buried epitaxial layer 36, which is defined by the distance between the top surface 12f of the mesa portion 12M and a bottom surface 36b of the buried epitaxial layer 36 along the z-direction, is in a range between about 3 nm and about 50 nm.

In some embodiments, the gate structure 50 occupies a middle portion of the semiconductor channel layers 16. Edge portions of the semiconductor channel layers 16 are covered by the inner spacers 32. The gate side wall spacers 30 are disposed on both sides of the gate structures 50 except between the semiconductor channel layers 16. In some embodiments, the sidewall spacers 30 and the inner spacers 32 may include a nitride, such as silicon nitride (Si3N4 or “SiN”), silicon carbon nitride (SiCN), and silicon carbon oxy-nitride (SiCON). The inner spacers 32 are interposed between the gate structure 50 and the epitaxial source/drain regions 40 to electrically isolate the gate structure 50 from epitaxial source/drain regions 40.

The silicide layers 54, which are interposed between the source/drain contacts 52 and epitaxial source/drain region 40, can include titanium silicide (TiSi), nickel silicide (NiSi), cobalt silicide (CoSi), platinum-silicide (PtSi), or a suitable silicide material. By way of example and not limitation, each silicide layer 54 may have a thickness between about 4 nm and about 8 nm. In some embodiments, the silicide layer reduces the contact resistance between the source/drain contact 53 and the epitaxial source/drain region 40.

In some embodiments, the ILD layer 44 includes one or more layers of dielectric material. In some embodiments, the ILD layer 44 is a silicon oxide based dielectric with nitrogen, hydrogen, carbon, or combinations thereof. According to some embodiments, the ILD layer 44 provides electrical isolation and structural support to the gate structure 50, the source/drain contacts 52, and the epitaxial source/drain regions 40.

As shown in FIG. 1A, the source/drain regions 40 extend towards the mesa portions 12M in the substrate 12, thereby, increasing the volume of the source/drain regions 40 without excessive growth over a top surface 16t of the topmost channel layer 16. In some embodiments, a top surface 40t of the source/drain region 40 may be positioned above the top surface 16t of the topmost channel layer 16 for a distance E40. In some embodiments, the distance E40 is in a range between about 10 nm and 15 nm. The relative low top profile of the source/drain regions 40 enables process uniformity during formation of the source/drain contacts 52, thereby reducing resistance loading between the source/drain regions 40 and the source/drain contacts 52.

FIG. 1B schematically demonstrates a semiconductor device 10a according to embodiments of the present disclosure. The semiconductor device 10a is similar to the semiconductor device 10 except that in the semiconductor device 10a, the first epitaxial source/drain layer 41 includes a bottom section 41B grown from sidewalls 12s of the mesa portion 12M and the top surface 36t of the buried epitaxial layer 36. As shown in FIG. 1B, the bottom section 41B is in contact with the top surface 36t of the buried epitaxial layer 36 and the two sidewalls 12s of the mesa portions 12M. In some embodiments, a height H12 of the sidewall 12s along the z-direction is in contact with the bottom section 41B. In some embodiments, the height H12 is in a range between about 0 nm and about 20 nm. In some embodiments, the channel sections 41C in the semiconductor device 10a are discreet portions without merging with one another or with the bottom section 41B.

FIGS. 1C and 1D schematically demonstrate a semiconductor device 10b according to embodiments of the present disclosure. The semiconductor device 10b is similar to the semiconductor device 10 except that in the semiconductor device 10b, the bottom profile 40P is a rounded profile. FIG. 1D is an enlarged view of a rectangular area 1D in FIG. 1C. As shown in FIG. 1D, the bottom profile 40P is a substantially continuous curve. In some embodiments, the bottom profile 40P may include two side portions 40Ps and a central portion 40Pc. Each side portion 40Ps may begin near the top surface 12f of the substrate and slopes downwards. The central portion 40Pc is substantially level with the x-axis. The side portions 40Ps and the central portion 40Pc form an angle θ1. In some embodiments, the angle θ1 is in a range between about 1200 and about 1800. The side portions 40Ps have a width 40Psx along the x-direction. The central portion 40Pc has a length 40Pcx along the x-direction. In some embodiments, a ratio of the length 40Psx over the length 40Pcx is in a range between about 0.1 and about 0.6.

FIG. 1E schematically demonstrates a semiconductor device 10c according to embodiments of the present disclosure. The semiconductor device 10c is similar to the semiconductor device 10b except that in the semiconductor device 10c, the bottom profile 40P has an angular profile. In some embodiments, the side portions 40Ps and the central portion 40Pc of the bottom profile 40P are substantially linear. Each side portion 40Ps may begin near the top surface 12f of the substrate and slopes downwards. In some embodiments, the side portions 40Ps and the central portion 40Pc form a half hexagon. In some embodiments, a ratio of the length 40Psx over the length 40Pcx is in a range between about 0.1 and about 0.6.

FIG. 1F schematically demonstrates a semiconductor device 10d according to embodiments of the present disclosure. The semiconductor device 10d is similar to the semiconductor device 10c except that in the semiconductor device 10d, the bottom profile 40P is substantially flat. In some embodiments, the bottom profile 40P may be a substantially planar surface disposed below the top surface 12f of the substrate 12. Portions of the mesa sidewalls 12s are exposed to the source/drain region 40 and in contact with the bottom section 41B of the first epitaxial layer 41. The bottom section 41B of the first epitaxial layer 41 merges with the channel sections 41C grown from the bottommost channel layers 16.

FIG. 1G schematically demonstrates a semiconductor device 10e according to embodiments of the present disclosure. The semiconductor device 10e is similar to the semiconductor device 10a shown in FIG. 1B. In the semiconductor device 10e, the sidewalls 12s of the mesa portion 12M are exposed to the source/drain region 40 and in contact with the bottom section 41B of the first epitaxial layer 41. The bottom profile 40P is rounded. In some embodiments, the bottom profile 40P may be similar to the bottom profile 40P in the semiconductor device 10b shown in FIG. 1C. The bottom section 41B of the first epitaxial layer 41 does not merge with the channel sections 41C. Because the bottom profile 40P is rounded, the bottom level 40b is substantially below the exposed sidewalls 12s. The drop height D40 is greater than the height H12 of the exposed sidewalls 12s. In some embodiments, a ratio of height H12 over the drop height D40 is in a range between 0 to 1.0, for example between about 0.3 and about 0.8.

FIG. 1H schematically demonstrates a semiconductor device 10f according to embodiments of the present disclosure. The semiconductor device 10f is similar to the semiconductor device 10e shown in FIG. 1G except that in the semiconductor device 10f, the bottom profile 40P is substantially flat. In some embodiments, the bottom profile 40P may be similar to the bottom profile 40P in the semiconductor device 10d shown in FIG. 1F. The sidewalls 12s of the mesa portion 12M are exposed to the source/drain region 40 and in contact with the bottom section 41B of the first epitaxial layer 41. The bottom section 41B of the first epitaxial layer 41 does not merge with the channel sections 41C. Because the bottom profile 40P is flat, the bottom level 40b is close to the level of the exposed sidewalls 12s.

FIG. 1I schematically demonstrates a semiconductor device 10g according to embodiments of the present disclosure. The semiconductor device 10g is similar to the semiconductor device 10f shown in FIG. 1H except that in the semiconductor device 10g, a top surface 41Bt of the bottom section 41B is a concaved surface resulting in the bulk epitaxial layer 43 drops below the top surface 12f of the substrate 12. As shown in FIG. 11, the bulk epitaxial layer 43 may drop below the top surface 12f of the substrate 12 for a drop distance D43. In some embodiments, the drop distance D43 is in a range between about 2 nm and 15 nm.

FIGS. 1J and 1K schematically demonstrate a semiconductor device 10h according to embodiments of the present disclosure. The semiconductor device 10h is similar to the semiconductor device 10a shown in FIG. 1B except that in the semiconductor device 10h, the bottom section 41B expands into the mesa portion 12M under in the inner spacers 32. FIG. 1K is an enlarged view of a rectangular area 1K in FIG. 1J. As shown in FIG. 1K, the first epitaxial source/drain layer 41 includes a bottom section 41B grown from sidewalls 12s of the mesa portion 12M and the top surface 36t of the buried epitaxial layer 36. The bottom section 41B is in contact with the top surface 36t of the buried epitaxial layer 36 and the two sidewalls 12s of the mesa portions 12M. The sidewalls 12s are curved in the x-z plane expanding into the mesa portions 12M. The bottom section 41B extends under the inner spacers 32 for a width W12. In some embodiments, the width W12 is in a range between about 1 nm and about 5 nm. As a result, the bottom section 41B has a first width W41bu under the top surface 12f and a second width W41Ba above the top surface 12f. The second width W41Ba is substantially similarly to a width W43 of the bulk epitaxial layer 43. The first width W41bu is greater than the second width W41Ba. In some embodiments, the first width W41bu is greater than the second width W41Ba for about 2 nm and 10 nm. The bottom section 41B of the first epitaxial layer 41 or the source/drain region 40 have corners formed around the lower most inner spacers 32. In some embodiments, the corners are in an angle θ2. In some embodiments, the angle θ2 is in a range between about 1800 and about 2400.

FIG. 1L schematically demonstrates a semiconductor device 10h according to embodiments of the present disclosure. The semiconductor device 10h is similar to the semiconductor device 10e shown in FIG. 1G except that in the semiconductor device 10h, the bottom profile 40P is an angular profile, similar to the bottom profile 40P in the semiconductor device 10c shown in FIG. 1E. The bottom profile 40P includes the side portions 40Ps and the central portion 40Pc. In some embodiments, the side portions 40Ps and the central portion 40Pc of the bottom profile 40P are substantially linear. Each side portion 40Ps may begin near the top surface 12f of the substrate and slopes downwards along the sidewalls 12s to the top surface 36t of the buried epitaxial layer 36. In some embodiments, the side portions 40Ps and the central portion 40Pc form a half hexagon.

FIG. 1M schematically demonstrates a semiconductor device 10j according to embodiments of the present disclosure. The semiconductor device 10j is similar to the semiconductor device 10h shown in FIGS. 1J and 1K except that in the semiconductor device 10j, the bottom profile 40P is substantially flat, similar to the bottom profile 40P in the semiconductor device 10d shown in FIG. 1F.

FIG. 1N schematically demonstrates a semiconductor device 10k according to embodiments of the present disclosure. The semiconductor device 10k is similar to the semiconductor device 10 except that in the semiconductor device 10k, a bottom dielectric layer 38 is formed between the source/drain region 40 and the buried epitaxial layer 36. The bottom dielectric layer 38 provides isolation around the epitaxial source/drain region 40. In the semiconductor device 10, the bottom dielectric layer 38 is formed on the buried epitaxial layer 36 and covers the buried epitaxial layer 36. In some embodiments, the bottom dielectric layer 38 may include suitable dielectric material, such as silicon nitride containing material, such as SiN, SiON, SiOCN, SiOC, SiCN, a metal oxide, such as AlOx, HfOx, or a combination thereof. In the semiconductor device 10k, the first epitaxial source/drain layer 41 does not include a bottom section 41B because the bottom dielectric layer 38 covers the buried epitaxial layer 36 and the substrate 12. As shown in FIG. 1N, the bulk epitaxial layer 43 is in contact with the bottom isolation layer 38 and defines the bottom profile 40P of the source/drain region 40.

FIG. 1O schematically demonstrates a semiconductor device 10m according to embodiments of the present disclosure. The semiconductor device 10m is similar to the semiconductor device 10k shown in FIG. 1N except that in the semiconductor device 10m, the first epitaxial source/drain layer 41 includes a sidewall section 41S grown from sidewalls 12s of the mesa portion 12M. As shown in FIG. 1O, the sidewall section 41S is in contact with the top surface 38t of the bottom dielectric layer 38 and the two sidewalls 12s of the mesa portions 12M. The bottom profile 40P of the source/drain region 40 is defined by the bulk epitaxial layer 43 and the sidewall sections 41S of the first epitaxial layer 41.

FIG. 1P schematically demonstrates a semiconductor device 10n according to embodiments of the present disclosure. The semiconductor device 10n is similar to the semiconductor device 10k shown in FIG. 1N except that in the semiconductor device 10m, the bottom dielectric section 38 has an opening exposing a portion of the buried epitaxial layer 36. As a result, the first epitaxial layer 41 includes a bottom section 41B grown from the buried epitaxial layer 36. The bottom section 41B may be disposed through a central portion of the bottom dielectric section 38. The bottom profile 40P of the source/drain region 40 is defined by the bulk epitaxial layer 43 and the bottom section 41B of the first epitaxial layer 41.

FIG. 1Q schematically demonstrates a semiconductor device 100 according to embodiments of the present disclosure. The semiconductor device 100 is similar to the semiconductor device 10m shown in FIG. 1O except that in the semiconductor device 100, the first epitaxial source/drain layer 41 includes a sidewall section 41S grown from sidewalls 12s of the mesa portion 12M. As shown in FIG. 1Q, the sidewall section 41S is in contact with the top surface 38t of the bottom dielectric layer 38 and the two sidewalls 12s of the mesa portions 12M, and the bottom section 41B may be disposed through a central portion of the bottom dielectric section 38. The bottom profile 40P of the source/drain region 40 is defined by the bulk epitaxial layer 43, the sidewall sections 41S of the first epitaxial layer 41, and the bottom section 41B of the epitaxial layer 41.

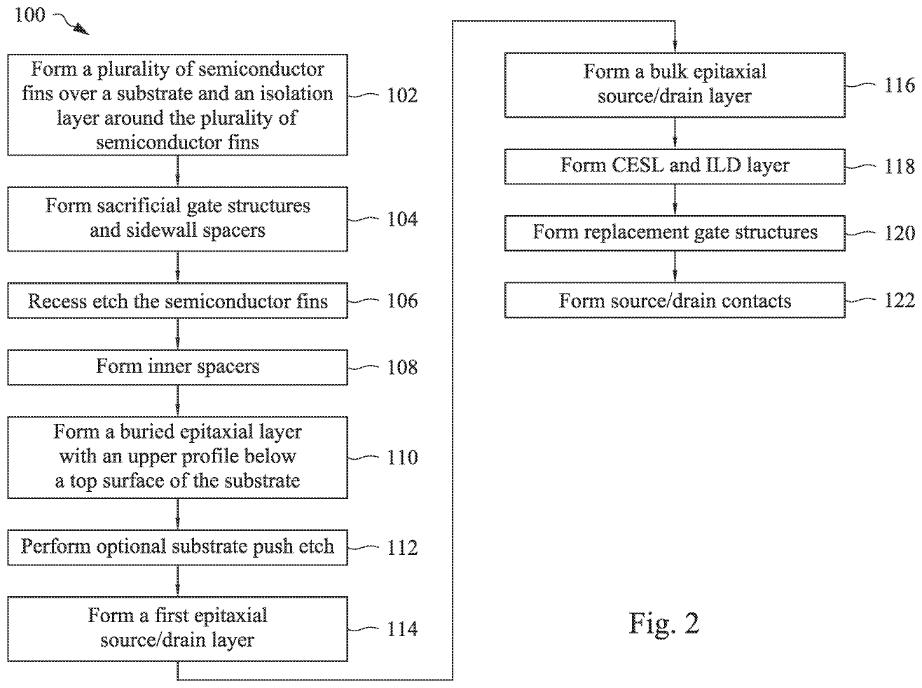

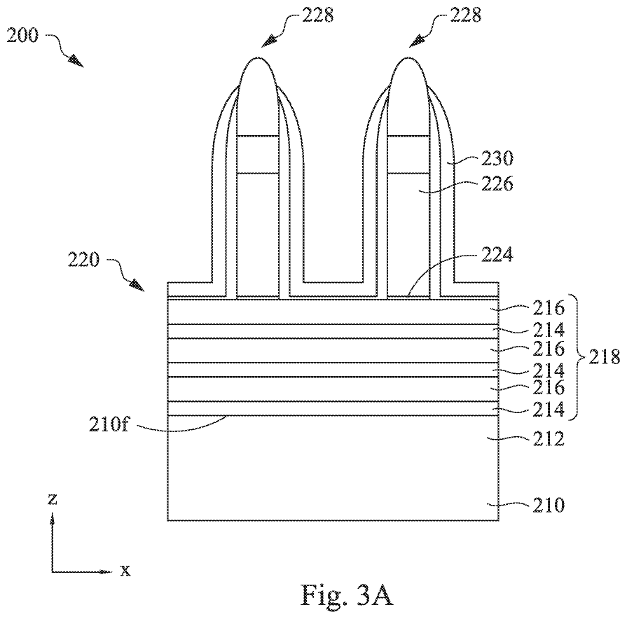

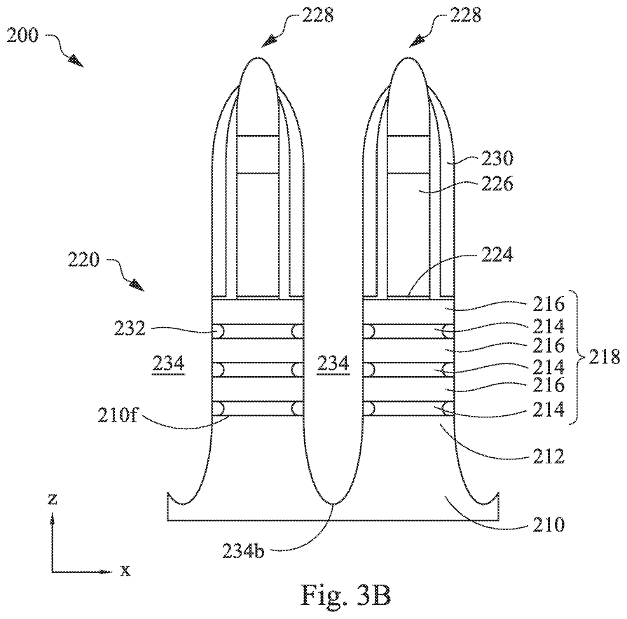

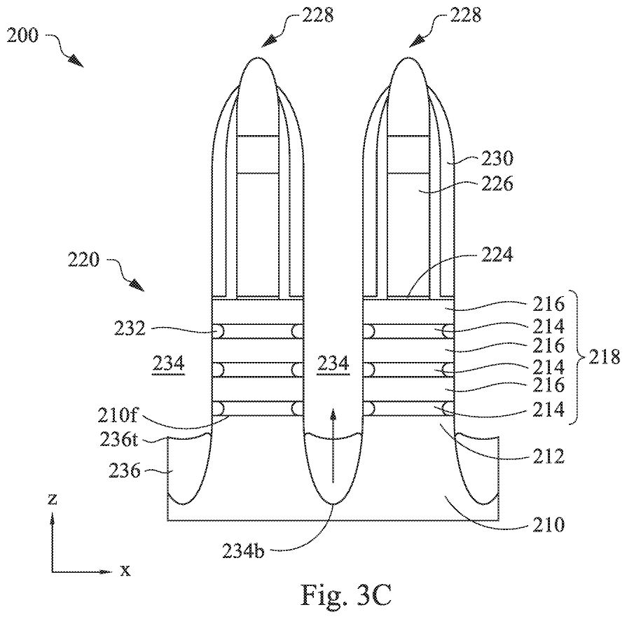

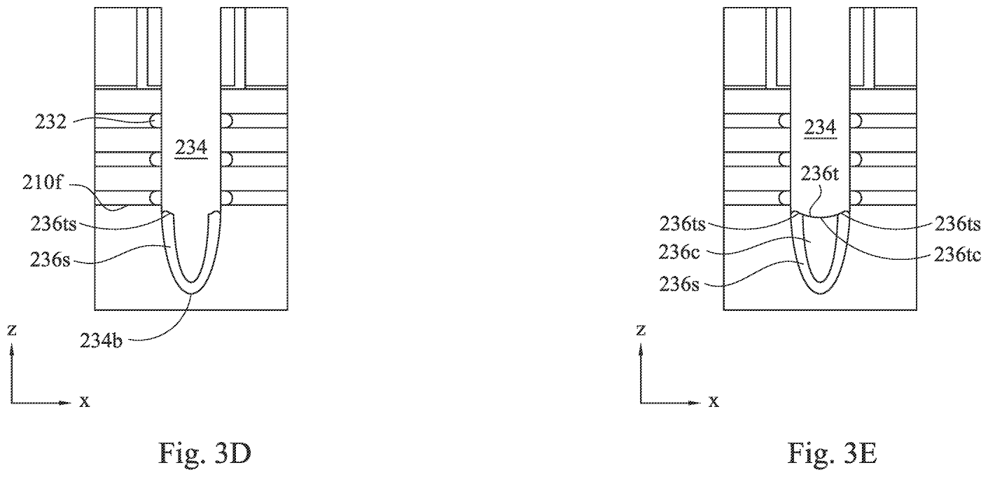

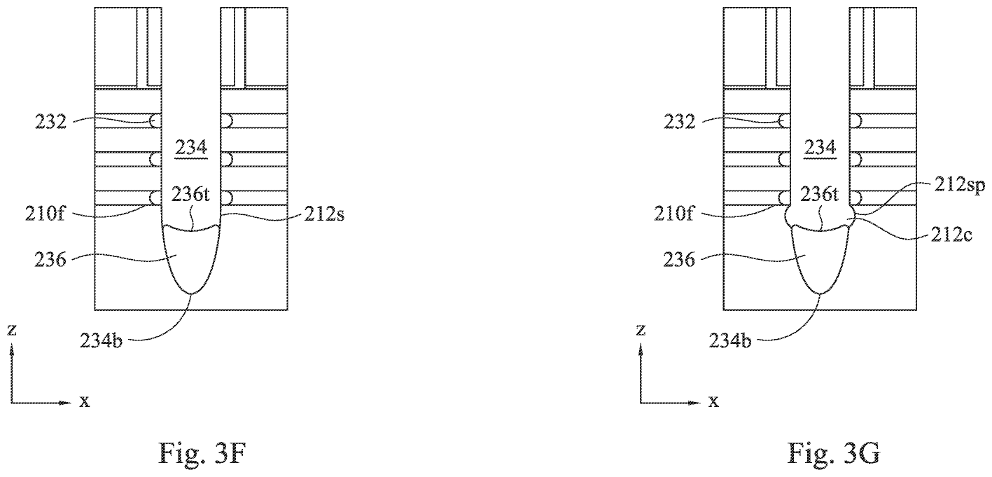

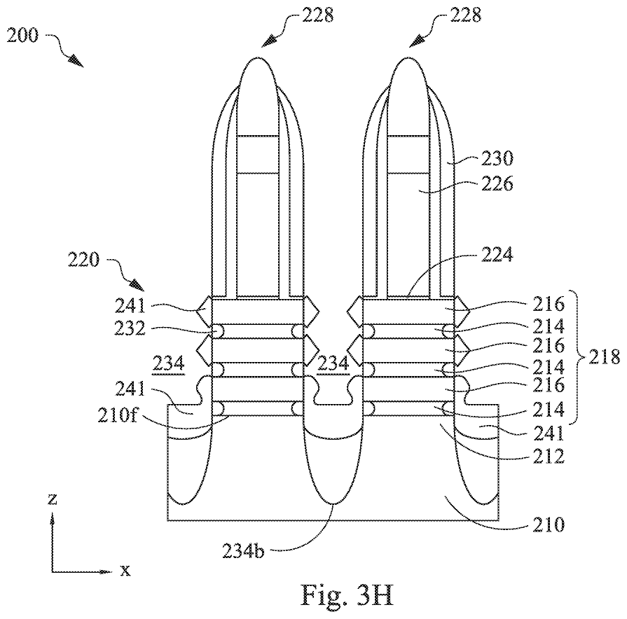

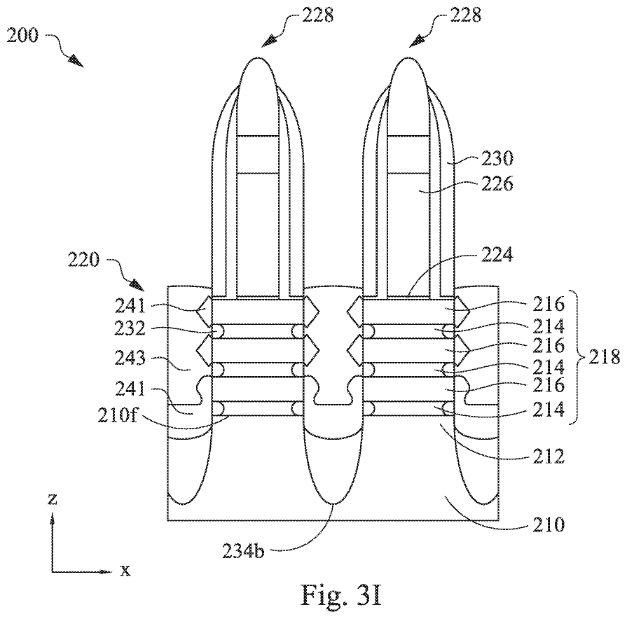

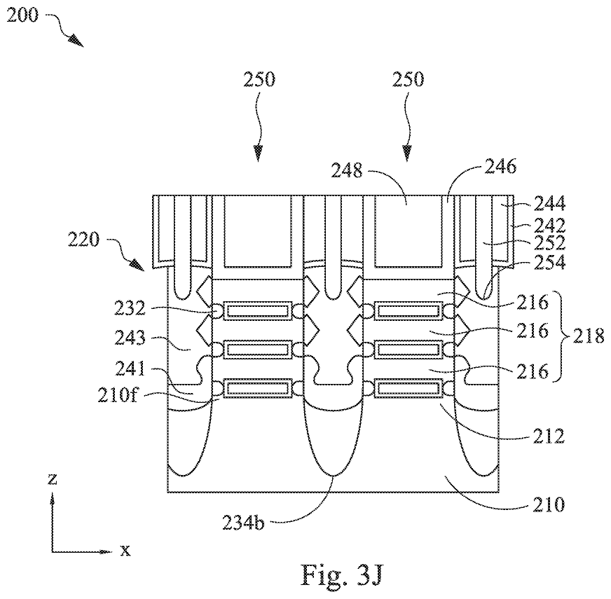

FIG. 2 is a flow chart of a method 100 for manufacturing of a semiconductor device according to embodiments of the present disclosure. FIGS. 3A-3J schematically illustrate various stages of manufacturing a semiconductor device 200 according to embodiments of the present disclosure. The semiconductor device 200 is similar to the semiconductor devices 10 and 10a-10j. Alternatively, the semiconductor devices 10 and 10a-10j may be fabricated using the method 100.

The method 100 begins at operation 102 where a plurality of semiconductor fins 220 are formed over a substrate 210, as shown in FIG. 3A. The substrate 210 is provided to form the semiconductor device 200 thereon. The substrate 210 may include a single crystalline semiconductor material such as, but not limited to Si, Ge, SiGe, GaAs, InSb, GaP, GaSb, InAlAs, InGaAs, GaSbP, GaAsSb, and InP. The substrate 210 may include various doping configurations depending on circuit design. For example, different doping profiles, e.g., n-wells, p-wells, may be formed in the substrate 210 in regions designed for different device types, such as n-type field effect transistors (NFET), and p-type field effect transistors (PFET). In some embodiments, the substrate 210 may be a silicon-on-insulator (SOI) substrate including an insulator structure (not shown) for enhancement.

The substrate 210 has a front surface 210f. A semiconductor stack 218 is then formed over the front surface 210f of the substrate 210. The stack includes alternating semiconductor layers made of different materials to facilitate formation of nanosheet channels in a multi-gate device, such as nanosheet channel FETs. In some embodiments, the stack includes first semiconductor layers 214 interposed by second semiconductor layers 216. The first semiconductor layers 214 and second semiconductor layers 216 have different oxidation rates and/or etch selectivity. In some embodiments, the front surface 210f of the substrate 210 may have (100) orientation or (110) orientation. The orientation of the front surface 210f determines the orientation of the layers in the stack 218, and epitaxial features, such as epitaxial source/drain regions formed from the semiconductor channel layers in the stack 218.

In later fabrication stages, portions of the second semiconductor layers 216 form nanosheet channels in a multi-gate device. Three first semiconductor layers 214 and three second semiconductor layers 216 are alternately arranged as illustrated in FIG. 3A as an example. More or less semiconductor layers 214 and 216 may be included in the stack depending on the desired number of channels in the semiconductor device to be formed. In some embodiments, the number of semiconductor layers 216 is between 1 and 10.

The semiconductor layers 214, 216 may be formed by a molecular beam epitaxy (MBE) process, a metalorganic chemical vapor deposition (MOCVD) process, and/or other suitable epitaxial growth processes. In some embodiments, the semiconductor layers 216 include the same material as the substrate 210. In some embodiments, the semiconductor layers 214 and 216 include different materials than the substrate 210. In some embodiments, the semiconductor layers 214 and 216 are made of materials having different lattice constants. In some embodiments, the first semiconductor layers 214 include an epitaxially grown silicon germanium (SiGe) layer and the second semiconductor layers 216 include an epitaxially grown silicon (Si) layer. Alternatively, in some embodiments, either of the semiconductor layers 214 and 216 may include other materials such as Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof.

The first semiconductor layers 214 in channel regions may eventually be removed and serve to define a vertical distance between adjacent channels for a subsequently formed multi-gate device. In some embodiments, the thickness of the first semiconductor layer 214 is equal to or greater than the thickness of the second semiconductor layer 216. In some embodiments, each semiconductor layer 214 has a thickness in a range between about 3 nm and about 15 nm. In some embodiments, each second semiconductor layer 216 has a thickness in a range between about 3 nm and about 15 nm. In some embodiments, the second semiconductor layers 216 in the stack are uniform in thickness.

The semiconductor fins 220 are formed from the stack and a portion of the substrate 210. The semiconductor fins 220 may be formed by patterning a hard mask (not shown) formed on the stack and one or more etching processes. Each semiconductor fin 220 has a channel portion 218 formed from the semiconductor layers 214, 216 and a well portion 212 formed from the substrate 210. The semiconductor fins 220 are formed along the X direction.

An isolation layer (not shown, but similar to the isolation layer 22 in FIG. 1B) is formed in the trenches between the semiconductor fins 220. The isolation layer is formed over the substrate 210 to cover the well portion 212 of the semiconductor fins 220. The isolation layer may be formed by a high-density plasma chemical vapor deposition (HDP-CVD), a flowable CVD (FCVD), or other suitable deposition process. In some embodiments, the isolation layer 222 may include silicon oxide, silicon nitride, silicon oxynitride, fluorine-doped silicate glass (FSG), a low-k dielectric, combinations thereof. In some embodiments, the isolation layer is formed to cover the semiconductor fins 220 by a suitable deposition process, such as atomic layer deposition (ALD), and then recess etched using a suitable anisotropic etching process to expose the channel portions 218 of the semiconductor fins 220.

In operation 104, sacrificial gate structures 228 and spacer layers 230 are then formed over the semiconductor fins 220, as shown in FIG. 3A. A sacrificial gate dielectric layer 224 is deposited over the exposed surfaces of the semiconductor device 200. The sacrificial gate dielectric layer 224 may be formed conformally over the semiconductor fins 220, and the isolation layer 222. In some embodiments, the sacrificial gate dielectric layer 224 may be deposited by a CVD process, a sub-atmospheric CVD (SACVD) process, a FCVD process, an ALD process, a PVD process, or other suitable process. The sacrificial gate dielectric layer 224 may include one or more layers of dielectric material, such as SiO2, SiN, a high-K dielectric material, and/or other suitable dielectric material.

A sacrificial gate electrode layer 226 is deposited over the sacrificial gate dielectric layer 224. The sacrificial gate electrode layer 226 may be blanket deposited on the over the sacrificial gate dielectric layer 224. The sacrificial gate electrode layer 226 includes silicon such as polycrystalline silicon or amorphous silicon. In some embodiments, the sacrificial gate electrode layer 226 is subjected to a planarization operation. The sacrificial gate electrode layer 226 may be deposited using CVD, including LPCVD and PECVD, PVD, ALD, or other suitable process. A patterning operation is the performed over the sacrificial gate dielectric layer 224 layer and the sacrificial gate electrode layer 226 to form the sacrificial gate structures 228, which cover formed over portions of the semiconductor fins 220 designed to be channel regions.

Gate sidewall spacers 230 are then formed on sidewalls of each sacrificial gate structures 228. After the sacrificial gate structures 228 are formed, the gate sidewall spacers 230 may be formed by a blanket deposition of an insulating material followed by anisotropic etch to remove insulating material from horizontal surfaces. The gate sidewall spacers 230 may have a thickness in a range between about 3 nm and about 8 nm. In some embodiments, the insulating material of the gate sidewall spacers 230 is a silicon nitride-based material, such as SIN, SiON, SiOCN or SiCN and combinations thereof. In FIG. 3A, the gate sidewall spacers 230 include two layers. In other embodiments, the gate sidewall spacers 230 may be formed from less or more layers of dielectric materials.

In operation 106, the semiconductor fins 220 on opposite sides of the sacrificial gate structure 228 are recess etched, forming source/drain recesses 234 between the neighboring sacrificial gate structures 228, as shown in FIG. 3B. The first semiconductor layers 214 and the second semiconductor layers 216 in the semiconductor fins 220 are etched down on both sides of the sacrificial gate structures 228 using etching operations. In some embodiments, all layers in the stack of the semiconductor fins 220 and a portion of the well portions 212 of the semiconductor fins 220 are etched. In some embodiments, suitable dry etching and/or wet etching may be used to remove the first semiconductor layers 214, the second semiconductor layers 216, and the substrate 210.

In operation 108, inner spacers 232 are formed on exposed ends of the first semiconductor layers 214 under the sacrificial gate structures 228, as shown in FIG. 3B. In some embodiments, the first semiconductor layers 214 can be selectively etched by using a wet etchant such as, but not limited to, ammonium hydroxide (NH4OH), tetramethylammonium hydroxide (TMAH), ethylenediamine pyrocatechol (EDP), or potassium hydroxide (KOH) solutions. In some embodiments, the amount of etching of the first semiconductor layer 214 is in a range between about 5 nm and about 10 nm along the X direction.

After forming the spacer cavities at opposite ends of the first semiconductor layers 214, the inner spacers 232 can be formed in the spacer cavities by conformally depositing an insulating layer. The insulation layer is then partially removed to form the inner spacer 232. The insulating layer can be formed by ALD or any other suitable method. The subsequent etch process removes most of the insulating layer except inside the cavities, resulting in the inner spacers 232. The inner spacers 232 includes two or more segments, alternately stacked with the second semiconductor layers 216.

The inner spacers 232 may be formed from a single layer or multiple layers of dielectric material. In some embodiments, the inner spacers 232 may include one of silicon nitride (SiN) and silicon oxide (SiO2), SiONC, or a combination thereof. The inner spacer 232 may have a thickness in a range from about 5 nm to about 10 nm along the X direction.

In operation 110, a buried epitaxial layer 236 is formed in lower portions of the source/drain recesses 234, as shown in FIG. 3C. In some embodiments, the buried epitaxial layer 236 fills the lower portions of the source/drain recesses 234 to a level below the top surface 210f of the substrate 210.

The material and shape of the buried epitaxial layer 236 may be selected according to achieve one or more purposes. For example, may define a bottom profile and crystalline direction of the subsequently formed source/drain region. Materials in the buried epitaxial layer 236 may provide crystalline transition from the substrate 210 to the subsequently formed source/drain region with improved adhesion. In some embodiments, the buried epitaxial layer 236 may also function as an alignment feature for back side source/drain contacts.

In some embodiments, the buried epitaxial layer 236 may be formed from a material to have etch selectivity relative to the material of the substrate 210, such as material in the well portion 212 of the semiconductor fin 220. In some embodiments, the buried epitaxial layer 236 may also have etch selectivity relative to the insulating material in the isolation layer. In some embodiments, the buried epitaxial layer 236 are formed from a semiconductor material with a high etch selectivity relative to Si. For example, the buried epitaxial layer 236 are formed are formed from SiGe.

The buried epitaxial layer 236 may be formed by any suitable method, such as by CVD, CVD epitaxy, molecular beam epitaxy (MBE), or any suitable deposition technique. In some embodiments, the buried epitaxial layer 236 are formed from undoped SiGe. In some embodiments, the buried epitaxial layer 236 are formed from undoped SiGe including an atomic concentration of Ge in a range between about 10% and about 100%. Alternatively, the buried epitaxial layer 236 may include other materials, such as Ge, a compound semiconductor such as SiC, GeAs, GaP, InP, InAs, and/or InSb, an alloy semiconductor such as GaAsP, AlInAs, AlGaAs, InGaAs, GaInP, and/or GaInAsP, or combinations thereof. In some embodiments, embodiments, the buried epitaxial layer 236 is undoped semiconductor layer. For example, the buried epitaxial layer 236 may include Si, SiB, Si1-xGex, or Si1-xGexB, wherein x is in a range between 0 and 0.5 and B concentration in a range between 1E19 atom*cm-3 and 3E21 atom*cm-3.

As discussed above, the front surface 236f of the buried epitaxial layer 236 may be shaped to achieve a desirable bottom profile for source/drain regions to be formed. In some embodiments, the profile of the top surface 236f may be tuned by adjusting crystal growth rates along different crystalline directions. In some embodiments, suitable growth rates along the (100) surface and the (110) surface may be selected to achieve a desired profile. In some embodiments, two or more grow steps may be performed to achieve a desired profile.

FIGS. 3D and 3E schematically demonstrate a method for growing the buried epitaxial layer 236 according to embodiments of the present disclosure. The buried epitaxial layer 236 may be formed in two steps. First, a sidewall layer 236s is conformally formed along the exposed surface of the substrate 210 in the recess 234, as shown in FIG. 3D. Next, a central layer 236c is formed by a bottom-up growth process, as shown in FIG. 3E. The top surface 236t may include two side sections 236ts and a central section 236tc. In some embodiments, an angle may be formed between the sidewall sections 236ts and the central section 236tc.

In other embodiments, the buried epitaxial layer 236 may be formed in a continuous process by adjusting growth rates along different directions.

In operation 112, an optional substrate push process is performed, as shown in FIGS. 3F and 3G. In some embodiments, the buried epitaxial layer 236 may be formed or etched back along the z-direction to a level such that portions of sidewalls 212s of the mesa region 212 are exposed to the source/drain recesses 234, as shown 3F. An etch process is then performed to selectively etch the substrate 210 horizontally along the X direction to form cavities 212c below the top surface 210f, as shown in FIG. 3G. The sidewalls 212s are pushed back to sidewalls 212sp. The cavities 212c are in connection with the source/drain recess 234 to provide additional volume to the source/drain regions. In some embodiments, the substrate 210 can be selectively etched by using a wet etchant such as, but not limited to, ammonium hydroxide (NH4OH), tetramethylammonium hydroxide (TMAH), ethylenediamine pyrocatechol (EDP), or potassium hydroxide (KOH) solutions. The cavities 212v are formed below the inner spacers 232.

The push operation enlarged the source/drain recesses 234, therefore, providing an increased volume for the subsequently formed source/drain region. Alternatively, the channel push operation may be omitted. In some embodiments, an etch back process of the buried epitaxial layer 236, as shown in FIG. 3F, may be performed alone without the push process shown in FIG. 3G.

In operation 114, a first epitaxial source/drain layer 241 is formed in the source/drain recess 234, as shown in FIG. 3H. In some embodiments, a preclean process may be performed prior to epitaxial growth of the first epitaxial source/drain layer 241. The first epitaxial source/drain layer 241 is formed by an epitaxial growth method using CVD, ALD or molecular beam epitaxy (MBE). The first epitaxial layer 241 is grow from exposed semiconductor surfaces, i.e., the sidewall 216s of the semiconductor layer 216 and the top surface 236t of the buried epitaxial layer 236. The first epitaxial source/drain layer 241 starts as discreet sections from the exposed semiconductor surfaces. For example, the first epitaxial source/drain layer 241 includes channel sections 241C grown from the sidewall 216s of the semiconductor layer 216, sidewall sections 241S grown from exposed sidewalls, a bottom section 241B grown from the buried epitaxial layer 236 via the opening 239. The channel sections 241C, sidewall sections 241S and the bottom section 241B are correctively referred to as the first epitaxial source/drain layer 241.

The first epitaxial source/drain layer 241 is grown to a desired thickness to enable quality crystalline growth in the subsequent bulk epitaxial growth. After operation 114, the channel sections 241C, sidewall sections 241S and the bottom section 241B may remain discreet or become merged. For example, in FIG. 3H, neighboring channel sections 241C may be merged or the lower most channel section 241C may merge with the sidewall section 241S. Alternatively, the bottom section 241B may merge with the sidewall sections 241S.

The first epitaxial source/drain layer 241 may include one or more layers of Si, SiP, SiC and SiCP for NFET or Si, SiGe, Ge for a PFET. For the PFET, p-type dopants, such as boron (B), may also be included in the first epitaxial source/drain layer 241. For NFET, n-type dopants, such as arsenic (As), phosphorous (P), or carbon (C), or combinations thereof, may also be included in the first epitaxial source/drain layer 241.

In some embodiments, the semiconductor device 200 is a p-type device and the first epitaxial source/drain layer 241 includes Si or SiGe with a p-type dopant, such as B or Ga. In some embodiments, the first epitaxial source/drain layer 41 may include Si1-xGexB, wherein x is in a range between 0 and 0.5 and B concentration in a range between 1E19 atom*cm-3 and 3E21 atom*cm-3.

In operation 116, a bulk epitaxial source/drain layer 243 is formed over the first epitaxial source/drain layer 241, as shown in FIG. 3I. The bulk epitaxial source/drain layer 243 fills the source/drain recess 234. The first epitaxial source/drain layer 241 and the bulk epitaxial source/drain layer 243 form epitaxial source/drain regions 240. Even though only one layer in FIG. 3I, the bulk epitaxial source/drain layer 243 may include two or more layers.

The bulk epitaxial source/drain layer 243 is epitaxially grown from the first epitaxial source/drain layer 241. The bulk epitaxial source/drain layer 243 has a higher concentration of dopants than the first epitaxial source/drain layer 241. In some embodiments, composition of the bulk epitaxial source/drain layer 243 is also different from the first epitaxial source/drain layer 241. The bulk epitaxial source/drain layer 243 and the first epitaxial source/drain layer 241 have different crystalline structures. The bulk epitaxial source/drain layer 243 may include one or more layers of Si, SiP, SiC and SiCP for NFET or Si, SiGe, Ge for a PFET. For the PFET, p-type dopants, such as boron (B), are also included in the bulk epitaxial source/drain layer 243. For NFET, n-type dopants, such as arsenic (As), phosphorous (P), or carbon (C), or combinations thereof, are included in the bulk epitaxial source/drain layer 243.

In some embodiments, the semiconductor device 200 is a p-type device and the bulk epitaxial source/drain layer 243 includes Si or SiGe with a p-type dopant, such as B or Ga. In some embodiments, the bulk epitaxial source/drain layer 43 may be Si1-xGexB, wherein x is in a range between 0.3 and 0.8 and B concentration in a range between 1E20 atom*cm-3 and 5E21 atom*cm-3.

In operation 118, a contact etch stop layer (CESL) 242 and an interlayer dielectric (ILD) layer 244 are formed over the exposed surfaces as shown in FIG. 3J. The CESL 242 is formed on the epitaxial source/drain regions 240 and the gate sidewall spacers 230. In some embodiments, the CESL 242 has a thickness in a range between about 1 nm and about 15 nm. The CESL 242 may include Si3N4, SiON, SiCN or any other suitable material, and may be formed by CVD, PVD, or ALD.

The interlayer dielectric (ILD) layer 244 is formed over the contract etch stop layer (CESL) 242. The materials for the ILD layer 244 include compounds comprising Si, O, C, and/or H, such as silicon oxide, SiCOH and SiOC. Organic materials, such as polymers, may be used for the ILD layer 244. After the ILD layer 244 is formed, a planarization operation, such as CMP, is performed to expose the sacrificial gate electrode layer 226 for subsequent removal of the sacrificial gate structures 228. The ILD layer 244 protects the epitaxial source/drain regions 240 during the removal of the sacrificial gate structures 228.

In operation 120, replacement gate structures 250 are formed in place of the sacrificial gate structures 228, as shown in FIG. 3J. The sacrificial gate structures 228 are first removed. Particularly, the sacrificial gate electrode layer 226 and the sacrificial gate dielectric layer 224 are removed sequentially to expose the channel portion 218. The first semiconductor layers 214 and the second semiconductor layers 216 are exposed. The first semiconductor layers 214 are then selectively removed using an etchant with a higher etch rate with respect to the first semiconductor layers 214 than the etch rate with respect to the second semiconductor layers 216. After the first semiconductor layers 214 are removed, the second semiconductor layers 216 are exposed resulting in a semiconductor channel region including the second semiconductor layers 216 in connection to the epitaxial source/drain regions 240.

The replacement gate structures 250 are then formed around the channel region. A gate dielectric layer 246 is formed around each of the second semiconductor layers 216 and a gate electrode layer 248 is formed on the gate dielectric layer 246. The gate dielectric layer 246 and the gate electrode layer 248 may be referred to as a replacement gate structure 250.

The gate dielectric layer 246 may be formed by CVD, ALD or any suitable method. In one embodiment, the gate dielectric layer 246 is formed using a highly conformal deposition process such as ALD in order to ensure the formation of a gate dielectric layer 246 having a uniform thickness around each of the second semiconductor layers 216. In some embodiments, the thickness of the gate dielectric layer 246 is in a range between about 1 nm and about 6 nm.

The gate dielectric layer 246 includes one or more layers of a dielectric material, such as silicon oxide, silicon nitride, or high-k dielectric material, other suitable dielectric material, and/or combinations thereof. Examples of high-k dielectric material include HfO2, HfSiO, HfSiON, HfTaO, HTiO, HfZrO, zirconium oxide, aluminum oxide, titanium oxide, hafnium dioxide-alumina (HfO2-Al2O3) alloy, other suitable high-k dielectric materials, and/or combinations thereof. In some embodiments, an interfacial layer (not shown) is formed between the second semiconductor layer 16 and the gate dielectric layer 246. In some embodiments, one or more work function adjustment layers (not shown) are interposed between the gate dielectric layer 246 and the gate electrode layer 248.

The gate electrode layer 248 is formed on the gate dielectric layer 246 to surround each of the second semiconductor layer 216 (i.e., each channel) and the gate dielectric layer 246. The gate electrode layer 248 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer 248 may be formed by CVD, ALD, electro-plating, or other suitable method.

In operation 122, source/drain contacts 252 may be formed, as shown in FIG. 3J. After the formation of the gate electrode layer 248, a planarization process, such as a CMP process, is performed to remove excess deposition of the gate electrode material and expose the top surface of the ILD layer 244. In some embodiments, source/drain contacts 252 are formed in the ILD layer 244. Prior to forming the source/drain contacts 252, contact holes are formed in the ILD layer 244, the CESL 242, and a portion of the epitaxial source/drain regions 240.

After formation of the front side source/drain contacts 252 are formed, a front side interconnect structure (not shown) is formed by a middle end of line process. The front side interconnect structure includes multiple dielectric layers having metal lines and vias formed therein. The metal lines and vias in the front side interconnect structure may be formed of copper or copper alloys using one or more damascene processes. The front side interconnect structure may include multiple sets of interlayer dielectric (ILD) layers and inter-metal dielectrics (IMDs) layers.

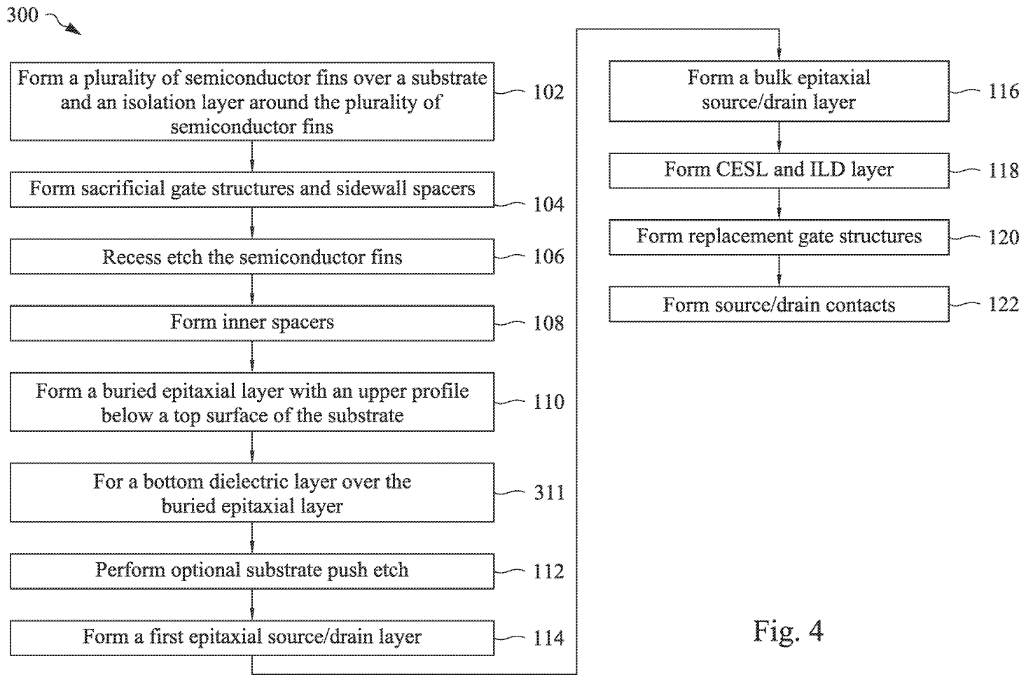

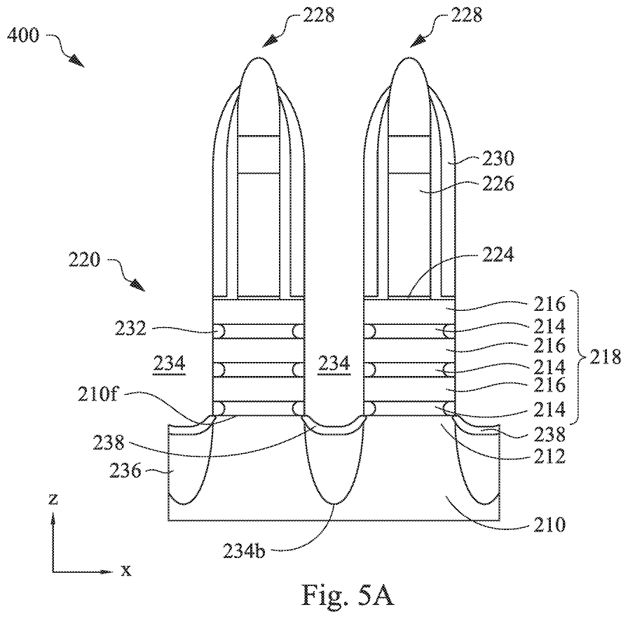

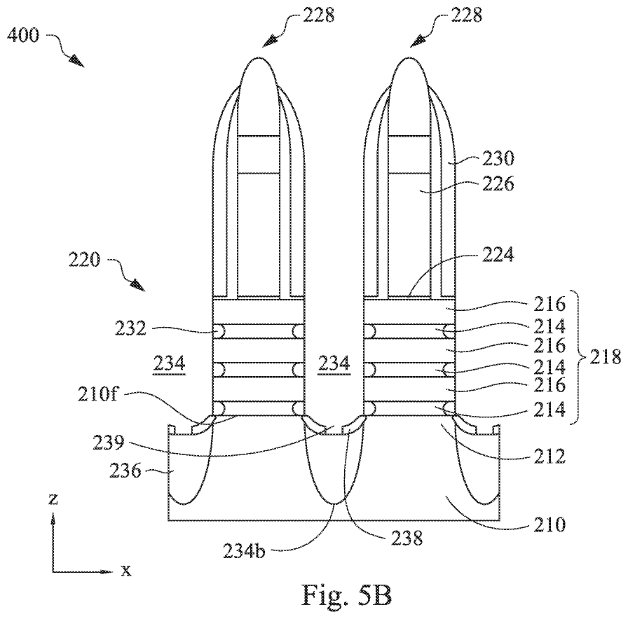

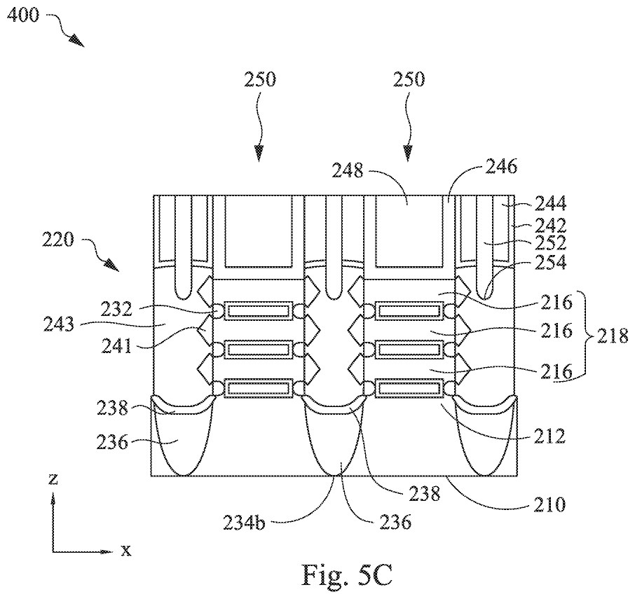

FIG. 4 is a flow chart of a method 300 for manufacturing of a semiconductor substrate according to embodiments of the present disclosure. FIGS. 5A-5C schematically illustrate various stages of manufacturing a semiconductor device 400 according to embodiments of the present disclosure. The semiconductor device 400 is similar to the semiconductor devices 10k-10o. The semiconductor devices may be fabricated using the method 300.

The method 300 is similar to the method 100 except that the method 300 includes an operation 311 after operations 102, 104, 106, 108, and 110. After operations 110, the semiconductor device 400 may be similar to the semiconductor device 200 shown in FIG. 3C.

In operation 311, a bottom dielectric layer 238 is formed over the buried epitaxial layer 236, as shown in FIGS. 5A-5B. The bottom dielectric layer 238 is formed on the front surface 236f of the buried epitaxial layer 236. The bottom dielectric layer 238 may also cover exposed surfaces of the isolation layer. The bottom dielectric layer 238 may include one or more layers of dielectric material. The bottom dielectric layer 238 may provide electrical isolation between the well portion 212 of the substrate 210 and the source/drain regions during operation.

The bottom dielectric layer 238 may be formed by a directional deposition process with bottom up to sidewall growth selectivity. For example, the bottom dielectric layer 238 may be formed by a directional PECVD process. In some embodiments, the bottom dielectric layer 238 may be formed by depositing a conformal dielectric layer over the exposed surface, as shown in FIG. 5A, and then selectively removing the conformal dielectric layer from vertical surfaces and outer surfaces, leaving a portion on a bottom of the source/drain recess 234, as shown in FIG. 5B. In some embodiments, the bottom dielectric layer 238 may be formed from any suitable dielectric material, such as silicon nitride containing material, such as SiN, SION, SiOCN, SiOC, SiCN, a metal oxide, such as AlOx, HfOx, or a combination thereof.

In some embodiments, the bottom dielectric layer 238 covers the top surface 236f of the buried epitaxial layer 236. The vertical location of the bottom dielectric layer 238 depend on the shape and location of the buried epitaxial layer 236. The bottom dielectric layer 238 may have a thickness over the buried epitaxial layer 236. In some embodiments, the thickness is in a range between about 0 nm and about 30 nm.

In some embodiments, an opening 239 is formed through the bottom dielectric layer 238 to expose a portion of the buried epitaxial layer 236, as shown in FIG. 5B. Depending on the design of the device, the opening 239 may be omitted. The opening 239 is formed so that a portion of the buried epitaxial layer 236 can be used as a seed layer during epitaxial growth of the source/drain region.

In some embodiments, the opening 239 may be formed by forming a pattern using photolithography technique and etching through the pattern using suitable etching process. In other embodiments, the opening 239 may be formed by directional etching.

After operation 311, operations 112, 114, 116, 118, 120, and 122 may be performed, resulting in the semiconductor device 400 as shown in FIG. 5C. The semiconductor device 400 includes the bottom dielectric layer 238 formed between the buried epitaxial layer 236 and the source/drain regions 240.

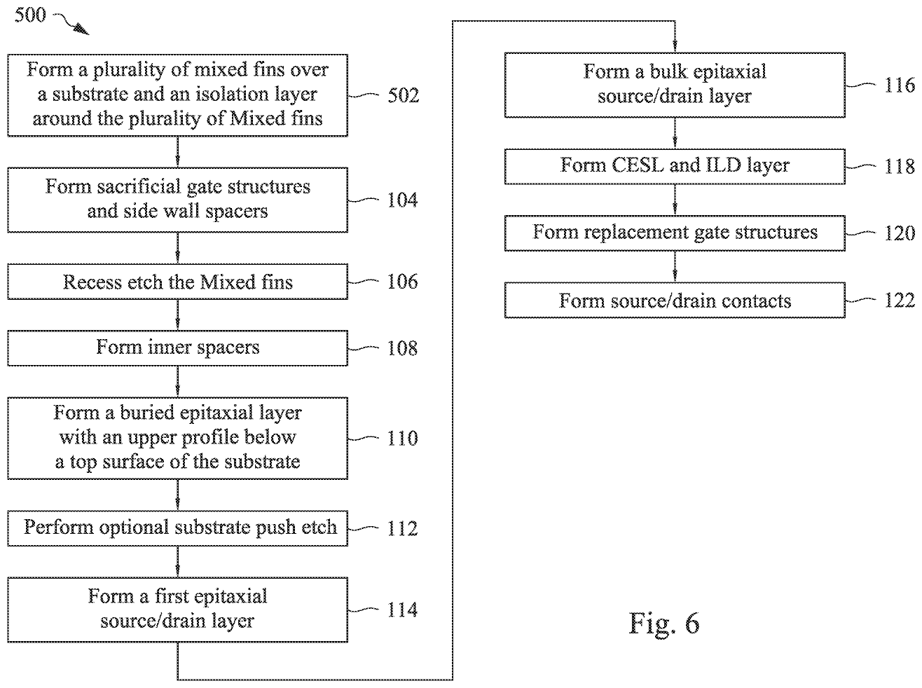

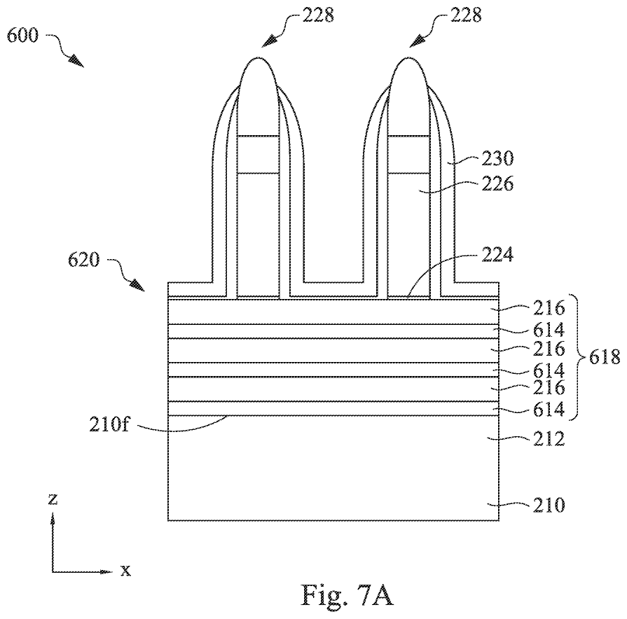

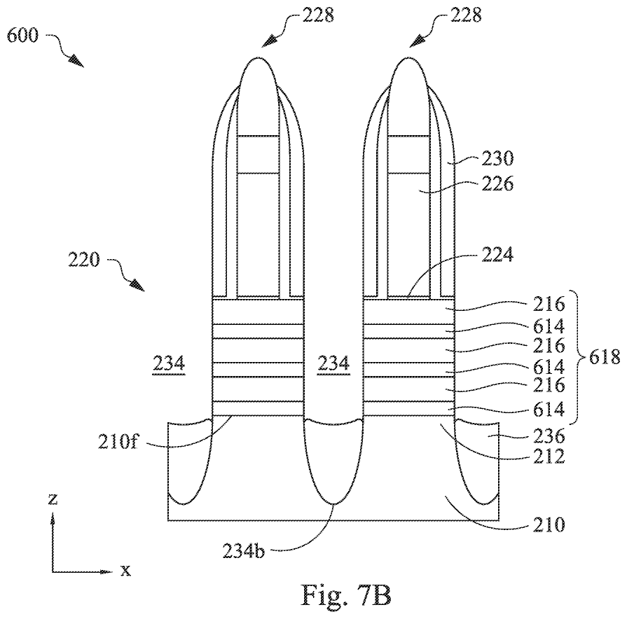

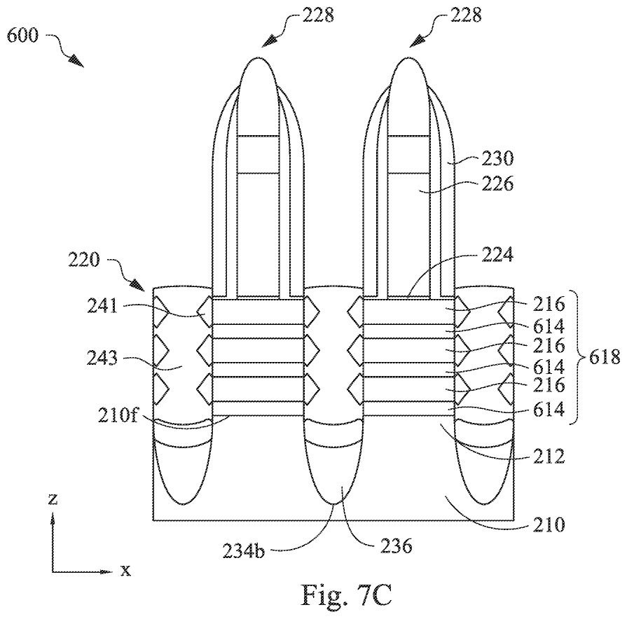

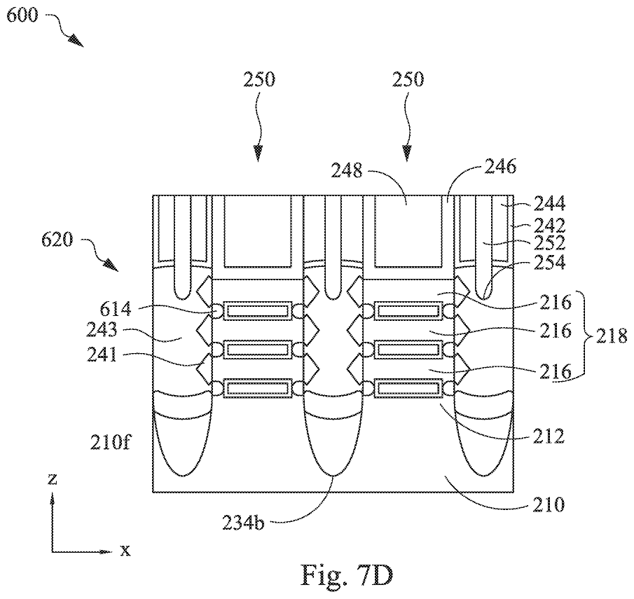

FIG. 6 is a flow chart of a method 500 for manufacturing of a semiconductor substrate according to embodiments of the present disclosure. FIGS. 7A-7D schematically illustrate various stages of manufacturing a semiconductor device 600 according to embodiments of the present disclosure. The semiconductor device 600 is similar to the semiconductor devices 10 and 10a-100. Alternatively, the semiconductor devices 10 and 10a-100 may be fabricated using the method 500.

The method 500 is similar to the methods 100 and 300 except that the method includes an operation 502 in which fin structures 620 including semiconductor layers 216 and sacrificial layers 614 are formed, as shown in FIG. 7A. The sacrificial layers 614 may be dielectric layers with maybe selectively removed from the semiconductor layers 216.

Using the dielectric sacrificial layers 614 in the fin structures 620 allows the method 500 to omit forming inner spacers during formation of the source/drain regions. As shown in FIGS. 7B and 7C. FIG. 7B schematically illustrates the semiconductor device 600 after operation 110 in the method 500. FIG. 7C schematically demonstrates the semiconductor device 600 after operation 116 in the method 500. FIG. 7D schematically illustrates the semiconductor device 600 after operation 122 in the method 500.

Various embodiments or examples described herein offer multiple advantages over the state-of-art technology. The semiconductor device according to the present disclosure has reduced channel resistance (Rch), with improved channel mobility, and minimized source/drain contact resistance loading.

It will be understood that not all advantages have been necessarily discussed herein, no particular advantage is required for all embodiments or examples, and other embodiments or examples may offer different advantages.

Some embodiments of the present provide a semiconductor device. The semiconductor device includes a semiconductor channel disposed over a top surface of a semiconductor substrate; an epitaxial source/drain region connected to the semiconductor channel, wherein the epitaxial source/drain region includes a sidewall connected to the semiconductor channel and a bottom surface extending below the top surface of the semiconductor substrate; and a buried epitaxial layer disposed below the epitaxial source/drain region, wherein a top surface of the buried epitaxial layer conforms with the bottom surface of the source/drain region, and the top surface of the buried epitaxial layer is disposed below the top surface of the semiconductor substrate.

Some embodiments of the present provide a semiconductor device. The semiconductor device includes a semiconductor substrate; two or more semiconductor channel layers vertically stacked above a top surface of the semiconductor substrate; two or more inner spacers disposed alternately stacked with the two or more semiconductor channel layers; and an epitaxial source/drain region comprising: a first epitaxial source/drain layer grown from the two or more semiconductor channel layers; and a bulk epitaxial source/drain layer grown from the first epitaxial source/drain layer, wherein a bottom surface of the epitaxial source/drain region extends below the top surface of the semiconductor substrate.

Some embodiments provide a method for forming a semiconductor device. The method includes forming a semiconductor fin on a top surface of a semiconductor substrate, wherein the semiconductor fin comprises first semiconductor layers and second semiconductor layers alternately arranged; forming a recess through the semiconductor fin and into the semiconductor substrate; forming a buried epitaxial layer in the recess, wherein a top surface of the buried epitaxial layer is below the top surface of the semiconductor substrate; and growing an epitaxial source/drain region over the buried epitaxial layer, wherein a bottom surface of the epitaxial source/drain region is below the top surface of the semiconductor substrate

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a semiconductor channel disposed over a top surface of a semiconductor substrate;
an epitaxial source/drain region connected to the semiconductor channel, wherein the epitaxial source/drain region includes a sidewall connected to the semiconductor channel and a bottom surface extending below the top surface of the semiconductor substrate; and
a buried epitaxial layer disposed below the epitaxial source/drain region, wherein a top surface of the buried epitaxial layer conforms with the bottom surface of the source/drain region, and the top surface of the buried epitaxial layer is disposed below the top surface of the semiconductor substrate.

2. The semiconductor device of claim 1, wherein the semiconductor channel comprises two or more semiconductor channel layers stacked over the top surface of the semiconductor substrate.

3. The semiconductor device of claim 2, wherein the bottom surface of the epitaxial sourced/drain region extends below the top surface of the semiconductor substrate in a range between about 5 nm and about 20 nm.

4. The semiconductor device of claim 3, wherein the bottom surface comprises:
a first sidewall section;
a second sidewall section; and
a central section connected to the first and second sidewall section, wherein the first and second sidewall sections slopes downwards.

5. The semiconductor device of claim 4, wherein the first sidewall section, the second sidewall section, and the central section are linear sections.

6. The semiconductor device of claim 4, wherein the first sidewall section, the second sidewall section, and the central section are rounded sections.

7. The semiconductor device of claim 4, wherein the first sidewall section and the central section form an angle in a range between 120° and 180°.

8. The semiconductor device of claim 2, wherein the epitaxial source/drain region is in contact with a sidewall of the semiconductor substrate disposed between the top surface of the semiconductor substrate and the bottom surface of the epitaxial source/drain region.

9. The semiconductor device of claim 2, further comprising a bottom dielectric layer disposed between the epitaxial source/drain region and the buried epitaxial layer.

10. The semiconductor device of claim 9, wherein the bottom dielectric layer includes an opening, and the epitaxial source/drain region extends below the bottom dielectric layer through the opening to contact the buried epitaxial layer.

11. The semiconductor device of claim 1, wherein the epitaxial source/drain region has a first width above the top surface of the semiconductor substrate and a second width below the top surface of the semiconductor substrate, and the second width is greater than the first width.

12. A semiconductor device, comprising:
a semiconductor substrate;
two or more semiconductor channel layers vertically stacked above a top surface of the semiconductor substrate;
two or more inner spacers disposed alternately stacked with the two or more semiconductor channel layers; and
an epitaxial source/drain region comprising:
a first epitaxial source/drain layer grown from the two or more semiconductor channel layers; and
a bulk epitaxial source/drain layer grown from the first epitaxial source/drain layer, wherein a bottom surface of the epitaxial source/drain region extends below the top surface of the semiconductor substrate.

13. The semiconductor device of claim 12, further comprising:
a buried epitaxial layer disposed below the bottom surface of the epitaxial source/drain region,
wherein the first epitaxial source/drain layer comprises:
two or more channel sections grown from the two or more semiconductor channel layers; and
a bottom section grown from the buried epitaxial layer.

14. The semiconductor device of claim 13, further comprising a bottom dielectric layer disposed between the buried epitaxial layer and the epitaxial source/drain region, wherein the bottom dielectric layer partially covers the buried epitaxial layer.

15. The semiconductor device of claim 13, wherein the epitaxial source/drain region is in contact with a sidewall of the semiconductor substrate disposed between the top surface of the semiconductor substrate and the bottom surface of the epitaxial source/drain region.

16. A method, comprising:
forming a semiconductor fin on a top surface of a semiconductor substrate, wherein the semiconductor fin comprises first semiconductor layers and second semiconductor layers alternately arranged;
forming a recess through the semiconductor fin and into the semiconductor substrate;
forming a buried epitaxial layer in the recess, wherein a top surface of the buried epitaxial layer is below the top surface of the semiconductor substrate; and
growing an epitaxial source/drain region over the buried epitaxial layer, wherein a bottom surface of the epitaxial source/drain region is below the top surface of the semiconductor substrate.

17. The method of claim 16, wherein growing the buried epitaxial layer comprises:
growing a conformal layer in the recess; and
growing a bottom-up layer over the conformal layer.

18. The method of claim 17, further comprising:
selectively etching back sidewalls of the semiconductor substrate between the top surface of the semiconductor substrate and a top surface of the buried epitaxial layer.

19. The method of claim 18, further comprising:
prior the etching back the semiconductor substrate, recess etching the buried epitaxial layer to expose the sidewalls of the semiconductor substrate between the top surface of the semiconductor substrate and the buried epitaxial layer.

20. The method of claim 16, further comprising forming a bottom dielectric layer over the buried epitaxial layer, wherein a top surface of the bottom dielectric layer is disposed below the top surface of the semiconductor substrate.
